(19) United States
(12) Patent Application Publication
(10) Pub. No.: US 2025/0042303 A1
(43) Pub. Date: Feb. 6, 2025

(54) VEHICLE CONTROL SYSTEM

(71) Applicant: TOYOTA JIDOSHA KABUSHIKI KAISHA, Toyota-shi (JP)

(72) Inventor: Shohei MATSUOKA, Toyota-shi (JP)

(73) Assignee: TOYOTA JIDOSHA KABUSHIKI KAISHA, Toyota-shi (JP)

(21) Appl. No.: 18/623,261

(22) Filed: Apr. 1, 2024

(30) Foreign Application Priority Data
Jul. 31, 2023 (JP) 2023-124063

(51) Int. Cl. B60L 58/26; B60L 58/16

(52) U.S. Cl. CPC B60L 58/26; B60L 58/16

(57) ABSTRACT

The vehicle control system according to the present disclosure includes a data collection unit that collects data related to driving characteristics of a vehicle by a user, an analysis unit that analyzes a burden on a battery that contributes to degradation of a battery mounted on the vehicle, using the collected data, and a control unit that cools the battery with a cooling intensity corresponding to an analysis result. Accordingly, the vehicle control system according to the present disclosure can effectively prevent or reduce degradation of the battery.

### CROSS-REFERENCE TO RELATED APPLICATION

This application claims priority to Japanese Patent Application No. 2023-124063 filed on Jul. 31, 2023, incorporated herein by reference in its entirety.

### BACKGROUND

### 1. Technical Field

The present disclosure relates to vehicle control systems.

### 2. Description of Related Art

In recent years, a technology for optimizing vehicle equipment according to user's driving characteristics has been increasingly developed. Japanese Unexamined Patent Application Publication No. 2020-158003 (JP 2020-158003 A) discloses a vehicle settings inheritance system. The vehicle settings inheritance system optimizes equipment of a second vehicle based on user's characteristic information learned in a first vehicle.

### SUMMARY

JP 2020-158003 A merely describes optimizing vehicle equipment such as steering feeling and seat position according to user's driving characteristics. JP 2020-158003 A does not describe taking appropriate measures to prevent or reduce degradation of a battery mounted on a vehicle. That is, the system disclosed in JP 2020-158003 A is disadvantageous in that it cannot perform an appropriate process for preventing or reducing degradation of a battery mounted on a vehicle according to user's driving characteristics.

The present disclosure was made in view of the above circumstances, and it is an object of the present disclosure to provide a vehicle control system that can effectively prevent or reduce degradation of a battery mounted on a vehicle.

A vehicle control system according to the present disclosure includes: a data collection unit configured to collect data on driving characteristics of a vehicle by a user;
an analysis unit configured to analyze, using the collected data, a burden on a battery mounted on the vehicle that contributes to degradation of the battery; and
a control unit configured to cool the battery with a cooling intensity according to an analysis result.
   This vehicle control system can effectively prevent or reduce degradation of the battery mounted on the vehicle by adjusting the cooling intensity for the battery according to the user's driving characteristics.

According to the present disclosure, it is possible to provide a vehicle control system that can effectively prevent or reduce degradation of a battery mounted on a vehicle.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 shows an example of the configuration of a vehicle control system according to a first embodiment;

FIG. 2 is a flowchart showing the operation of a vehicle control device provided in the vehicle control system shown in FIG. 1; and

FIG. 3 shows an example of the configuration of a vehicle control system according to a second embodiment.

### DETAILED DESCRIPTION OF EMBODIMENTS

Hereinafter, the present disclosure will be described through embodiments of the disclosure, but the disclosure according to the claims is not limited to the following embodiments. Further, not all of the configurations described in the embodiments are essential as means for solving the problem. For clarity of explanation, the following description and the drawings are omitted and simplified as appropriate. In the drawings, the same elements are denoted by the same reference numerals, and redundant descriptions are omitted as necessary.

### First Embodiment

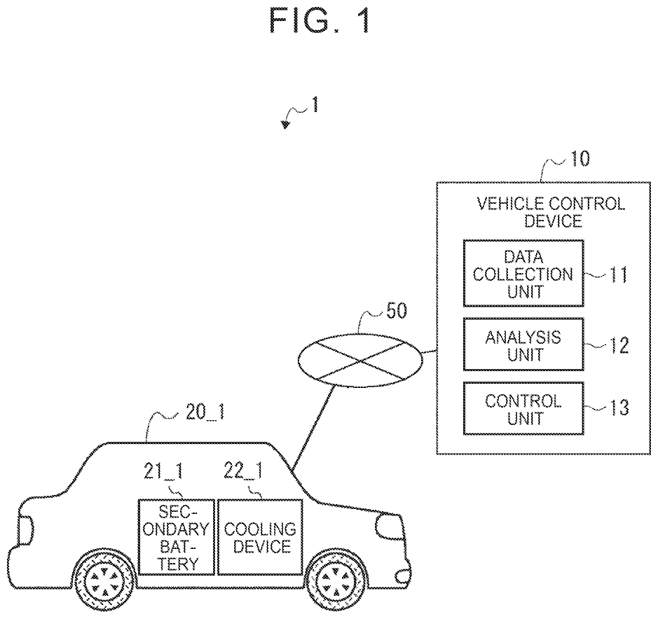

FIG. 1 shows an example of the configuration of a vehicle control system 1 according to a first embodiment. The vehicle control system 1 can effectively prevent or reduce degradation of the battery mounted on the vehicle by adjusting the cooling intensity for the battery mounted on the vehicle in accordance with the driving characteristics of the user. Hereinafter, it will be described in detail.

As shown in FIG. 1, the vehicle control system 1 includes a vehicle control device 10, a vehicle 20_1, and a network 50. The vehicle control device 10 may be referred to as a vehicle control system alone. The vehicle control device 10 and the vehicle 20_1 are configured to be able to communicate with each other via a wired or wireless network 50. The vehicle control device 10 may be mounted on the vehicle 20_1 or may be provided separately from the vehicle 20_1.

The vehicle 20_1 is a battery electric vehicle owned by the user U1. The vehicle 20_1 is provided with a rechargeable secondary battery 21_1 such as a lithium ion battery and a cooling device 22_1 for cooling the secondary battery 21_1. The cooling device 22_1 may be an air-cooling type cooling device such as a fan or a water-cooling type cooling device using a pipe or the like through which coolant flows.

The vehicle control device 10 is a device that adjusts the cooling intensity of the cooling device 22_1 of the secondary battery 21_1 mounted on the vehicle 20_1 in accordance with the driving characteristics of the user U1. Specifically, the vehicle control device 10 includes a data collection unit 11, an analysis unit 12, and a control unit 13.

The data collection unit 11 collects data related to the driving characteristics of the vehicles 20_1 by the user U1. The data on the driving characteristics of the vehicle 20_1 by the user U1 is, for example, data related to the traveled distance per predetermined period of the vehicle 20_1 by the user U1, the speed per predetermined period of the vehicle 20_1 by the user U1 (that is, the mean speed), or the accelerator operation amount per predetermined period of the vehicle 20_1 by the user U1.

The analysis unit 12 uses the data collected by the data collection unit 11 to analyze the burden on the secondary battery 21_1 that contributes to degradation of the secondary battery 21_1 mounted on the vehicle 20_1. The burden imposed on the secondary battery is, in other words, a load applied to the secondary battery.

For example, the analysis unit 12 determines that the burden on the secondary battery 21_1 is larger as the traveled distance per predetermined period of the vehicle 20_1 by the user U1 is longer. The analysis unit 12 determines that the burden on the secondary battery 21_1 is smaller as the traveled distance per predetermined period of the vehicle 20_1 by the user U1 is shorter. Alternatively, the analysis unit 12 determines that the burden on the secondary battery 21_1 is larger as the speed per predetermined period of the vehicle 20_1 by the user U1 is higher. The analysis unit 12 determines that the burden on the secondary battery 21_1 is smaller as the speed per predetermined period of the vehicle 20_1 by the user U1 is slower. Alternatively, the analysis unit 12 determines that the burden on the secondary battery 21_1 is larger as the accelerator operation amount per predetermined period of the vehicle 20_1 by the user U1 is larger. The analysis unit 12 determines that the burden on the secondary battery 21_1 is smaller as the accelerator operation amount per predetermined period of the vehicle 20_1 by the user U1 is smaller. The analysis unit 12 may analyze the load on the secondary battery 21_1 from other driving characteristics. Then, the analysis unit 12, for example, digitizes the analysis result of the burden on the secondary battery 21_1 and outputs the result.

The control unit 13 causes the cooling device 22_1 to cool the secondary battery 21_1 with the cooling intensity corresponding to the analysis result by the analysis unit 12. For example, when the burden (a numerical value indicating a burden) on the secondary battery 21_1 is equal to or greater than a predetermined value, the control unit 13 increases the cooling intensity for the secondary battery 21_1 by the cooling device 22_1. As a result, the burden on the secondary battery 21_1 is reduced, and thus degradation of the secondary battery 21_1 is reduced. In addition, when the burden (a numerical value indicating a burden) on the secondary battery 21_1 is less than the predetermined value, the control unit 13 weakens or maintains the cooling intensity for the secondary battery 21_1 by the cooling device 22_1. Thereby, the load of the cooling process of the cooling device 22_1 is reduced.

In addition, when the number of times that the burden (a numerical value indicating a burden) on the secondary battery 21_1 becomes equal to or greater than a predetermined value reaches a predetermined value, the control unit 13 may be configured not only to increase the cooling intensity for the secondary battery 21_1 by the cooling device 22_1 but also to decrease the upper limit value of the current to be supplied to the secondary battery 21_1 during charging. As a result, the charging time of the secondary battery 21_1 becomes longer, but the burden on the secondary battery 21_1 during charging is reduced, so that degradation of the secondary battery 21_1 is further reduced.

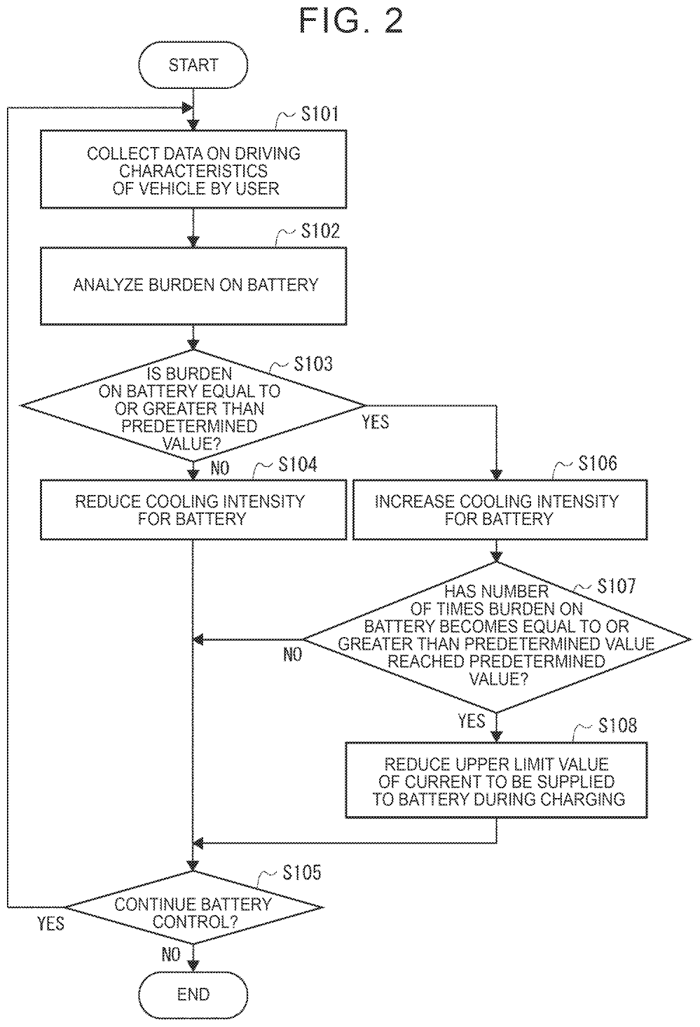

Next, the operation of the vehicle-control device 10 will be described with reference to FIG. 2. FIG. 2 is a flow chart illustrating an operation of the vehicle control device 10.

First, the vehicle control device 10 collects the driving characteristics of the vehicle 20_1 by the user U1 (S101).

Thereafter, the vehicle control device 10 analyzes, using the collected data, the burden on the secondary battery 21_1 that contributes to degradation of the secondary battery 21_1 mounted on the vehicle 20_1 (S102).

For example, when the burden (a numerical value indicating the burden) on the secondary battery 21_1 is less than the predetermined value (NO in S103), the vehicle control device 10 reduces or maintains the cooling intensity for the secondary battery 21_1 by the cooling device 22_1 (S104). Thereby, the load of the cooling process of the cooling device 22_1 is reduced.

On the other hand, when the burden (a numerical value indicating the burden) on the secondary battery 21_1 is equal to or greater than a predetermined value (YES in S103), the vehicle control device 10 increases the cooling intensity for the secondary battery 21_1 by the cooling device 22_1 (S106). As a result, the burden on the secondary battery 21_1 is reduced, and thus degradation of the secondary battery 21_1 is reduced.

Further, when the number of times that the burden on the secondary battery 21_1 becomes equal to or greater than a predetermined value (a numerical value representing a burden) reaches a predetermined value (YES of S107), the vehicle control device 10 not only increases the cooling intensity for the secondary battery 21_1 by the cooling device 22_1 but also decreases the upper limit value of the current to be supplied to the secondary battery 21_1 during charging (S108). As a result, the charging time of the secondary battery 21_1 becomes longer. However, since the burden on the secondary battery 21_1 during charging is reduced, degradation of the secondary battery 21_1 is further reduced.

After any one of S104 process, NO process of S107 process, and S108 process, when the vehicle control device 10 continues the cooling control of the secondary battery 21_1 (YES of S105), the processing returns to the data collection process (S101). When the cooling control of the secondary battery 21_1 is not continued (NO of S105), the vehicle-control device 10 terminates the process.

As described above, the vehicle control system 1 according to the present embodiment adjusts the cooling intensity for the cooling device 22_1 of the secondary battery 21_1 mounted on the vehicle 20_1 according to the driving characteristics of the user U1. By adjusting the cooling rate in this way, degradation of the secondary battery 21_1 can be effectively prevented or reduced.

### Second Embodiment

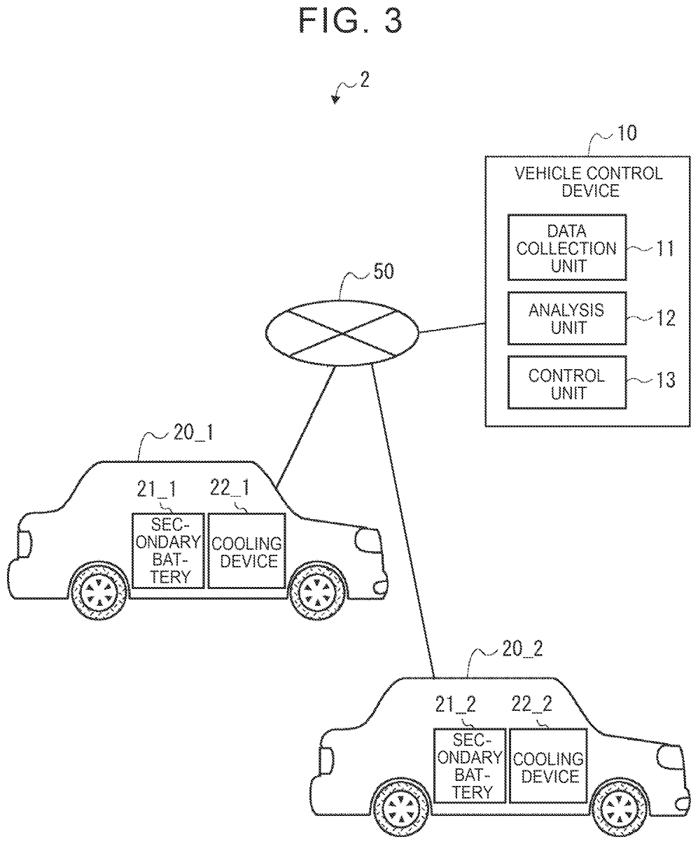

FIG. 3 shows an example of the configuration of a vehicle control system 2 according to a second embodiment. The vehicle control system 2 further includes a vehicle 20_2 as compared with the vehicle control system 1. The vehicle control device 10 and the vehicles 20_1 and 20_2 are configured to be able to communicate with each other via a wired or wireless network 50.

The vehicle 20_2 is a battery electric vehicle owned by the user U1. The vehicle 20_2 is provided with a rechargeable secondary battery 21_2 such as a lithium ion battery and a cooling device 22_2 for cooling the secondary battery 21_2. The cooling device 22_2 may be an air-cooling type cooling device such as a fan or a water-cooling type cooling device using a pipe or the like through which coolant flows.

The driving characteristics of the vehicle 20_2 by the user U1 tend to be similar to the driving characteristics of the vehicle 20_1 by the user U1. Therefore, in the present embodiment, the vehicle control device 10 adjusts the cooling intensity for the secondary battery 21_2 of the vehicle 20_2 based on the result of analysis of the driving characteristics of the vehicle 20_1 by the user U1. Thus, even when data is not collected from the vehicle 20_2, for example, when the vehicle 20_2 is a new vehicle, degradation of the secondary battery 21_2 is effectively reduced.

As described above, the vehicle control system according to the embodiment can effectively prevent or reduce degradation of the secondary battery by adjusting the cooling intensity for the secondary battery mounted on the vehicle in accordance with the driving characteristics of the user.

In addition, some or all of the processes of the vehicle control device 10 can be realized by causing a Central Processing Unit (CPU) to execute a computer program.

The programs described above include instructions (or software code) that, when loaded into a computer, cause the computer to perform one or more of the functions described in the embodiments. The program may be stored in a non-transitory computer-readable medium or a tangible storage medium. By way of example, and not limitation, computer-readable media or tangible storage media include Random-Access Memory (RAM), Read-Only Memory (ROM), flash memory, Solid-State Drive (SSD), or other memory techniques, CD-ROM, Digital Versatile Disc, Blu-ray disks or other optical disk storage, magnetic cassettes, magnetic tape, magnetic disk storage, or other magnetic storage devices. The program may be transmitted on a transitory computer readable medium or a communication medium. By way of example, and not limitation, transitory computer-readable media or communication media include electrical, optical, acoustic, or other forms of propagated signals.

Some or all of the above-described embodiments may be described as the following supplementary notes, but are not limited thereto.

### Appendix 1

A vehicle control method, in which a vehicle control system
collect data on driving characteristics of a vehicle by a user,
analyze, using the collected data, a burden on a battery mounted on the vehicle that contributes to degradation of the battery, and
cool the battery with a cooling intensity according to an analysis result.

### Appendix 2

A control program that causes a computer to execute
a process of collecting data on driving characteristics of a vehicle by a user,
a process of analyzing, using the collected data, a burden on a battery mounted on the vehicle that contributes to degradation of the battery, and
a process of cooling the battery with a cooling intensity according to an analysis result.

What is claimed is:

1. A vehicle control system, comprising:
a data collection unit configured to collect data on driving characteristics of a vehicle by a user;
an analysis unit configured to analyze, using the collected data, a burden on a battery mounted on the vehicle that contributes to degradation of the battery; and
a control unit configured to cool the battery with a cooling intensity according to an analysis result.

2. The vehicle control system according to claim 1, wherein the control unit is configured to increase the cooling intensity for the battery as the burden on the battery increases.

3. The vehicle control system according to claim 2, wherein the analysis unit is configured to determine that the burden on the battery is greater as a traveled distance of the vehicle per a predetermined period is greater, a speed of the vehicle per the predetermined period is higher, or an accelerator operation amount of the vehicle per the predetermined period is greater.

4. The vehicle control system according to claim 2, wherein the control unit is configured to, when the number of times the analysis unit determines that the burden on the battery is great reaches a predetermined value, increase the cooling intensity and reduce an upper limit value of a current to be supplied to the battery during charging of the battery.

5. The vehicle control system according to claim 1, wherein a battery mounted on a vehicle of the user different from the vehicle is cooled with the cooling intensity according to the analysis result.
